(19) United States
(12) Patent Application Publication
(10) Pub. No.: US 2011/0181447 A1
(43) Pub. Date: Jul. 28, 2011

(54) INPUT DEVICE AND INPUT SYSTEM UTILIZED THEREBY

(75) Inventor: LUNG DAI, Tu-Cheng (TW)

(73) Assignee: HON HAI PRECISION INDUSTRY CO., LTD., Tu-Cheng (TW)

(21) Appl. No.: 12/957,268

(22) Filed: Nov. 30, 2010

(30) Foreign Application Priority Data
Jan. 22, 2010 (TW) 99101866

(51) Int. Cl. H03M 11/00

(52) U.S. Cl. 341/22

(57) ABSTRACT

An input device includes a plurality of keys, each having an exclusive input key code corresponding to an illumination unit, a notification unit and a detection unit. An electronic device includes an execution unit and a first comparison unit. The execution unit generates a preset key code and an illumination command. The corresponding illumination unit emits light according to the illumination command. The detection unit detects whether one of the keys is activated, if a key is activated, generate an input key code. The comparison unit compares the preset key code and the input key code. If the two codes are the same, the comparison unit generates a stop signal. The illumination unit stops shinning according to the stop signal. If the two codes are different, the comparison unit generates a notification. The notification unit issues a notification accordingly.

### BACKGROUND

1. Technical Field

The present disclosure relates to an input device.

2. Description of Related Art

When using a dancing mat in combination with a computer with a display, a user needs to follow prompt information generated by the computer to find the corresponding key and press the corresponding key quickly. It is complicated and difficult for the user to learn.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a block diagram of an input system in accordance with one exemplary embodiment.

FIG. 2 is a flowchart of an input system in accordance with one exemplary embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

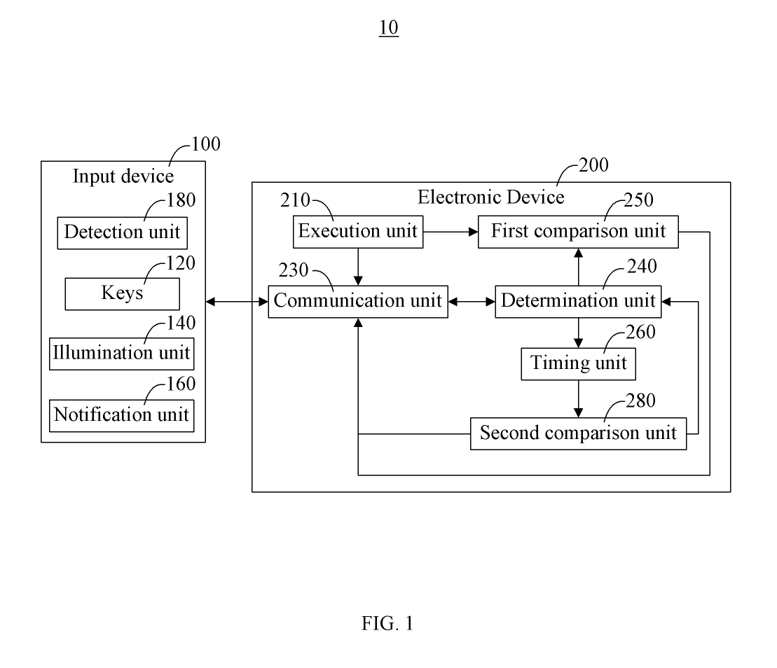

Referring to FIG. 1, an input system 10 includes an input device 100 and an electronic device 200. The input device 100 and the electronic device 200 are connected in a wired or a wireless manner. The input device 100 may be a keyboard or a dancing mat. The electronic device 200 may be a computer, a television or a display.

The input device 100 includes a plurality of keys 120 each having an exclusive input key code, a plurality of illumination units 140, a plurality of notification units 160 and a plurality of detection units 180. Each of the keys 120 corresponds to an illumination unit 140, a notification unit 160 and a detection unit 180. The illumination unit 140 is used for emitting light. The illumination unit 140 may be an LED. The keys 120 may be transparent keys or translucent keys allowing light emitted by the illumination unit 140 to pass there through. The notification unit 160 may be a vibration motor. The detection unit 180 detects whether the keys 120 being deactivated, and generates a corresponding input key code.

The electronic device 200 includes an execution unit 210, a communication unit 230, a determination unit 240, a first comparison unit 250, a timing unit 260 and a second comparison unit 280.

The execution unit 210 generates a preset key code and an illumination command as driven by an application. The execution unit 210 sends the preset key code to the first comparison unit 250. The communication unit 230 transmits the illumination command to the illumination unit 140 and the key 120 which the input key code is the same with the preset key code is lit.

The communication unit 230 also transmits the input key code to the determination unit 240. The determination unit 240 determines whether an input key code is received, and transmits the input key code to the first comparison unit 250. The first comparison unit 250 compares the preset key code and the input key code, and if the input key code and the preset key code are the same, the right key is activated and the first comparison unit 250 generates a stop signal to the corresponding illumination unit 140 through the communication unit 230 and the illumination unit 140 stops emitting light. If the input key code and the preset key code are different, the erroneous key is activated and the comparison unit 250 generates an error notification to the notification unit 160 through the communication unit 230.

The notification unit 160 generates a notification in response to error notification. In the embodiment, the notification unit 160 generates a vibration, but alternatively issues an image, audio, or video notification.

If the input key code is not received, the determination unit 240 sends a timing signal to the timing unit 260 which measures non-operating duration for the second comparison unit 280.

The second comparison unit 280 houses a predetermined non-operating duration value, which it compares with the received non-operating duration, and if the received non-operating duration is at least the predetermined non-operating duration, it determined that an erroneous key has been activated, and the comparison unit 280 sends an error notification to the notification unit 160 through the communication unit 230. The notification unit 160 according to the key 120 which is activated issues a notification in response to error notification. In the embodiment, the predetermined non-operating duration value is equal to the length of time required for the execution unit 210 to generate a preset key code.

In operation of input device 100 as disclose, in combination with the electronic device 200, when the execution unit 210 generates a preset key code, the illumination unit 140 illuminates the key 120 matching the preset key code.

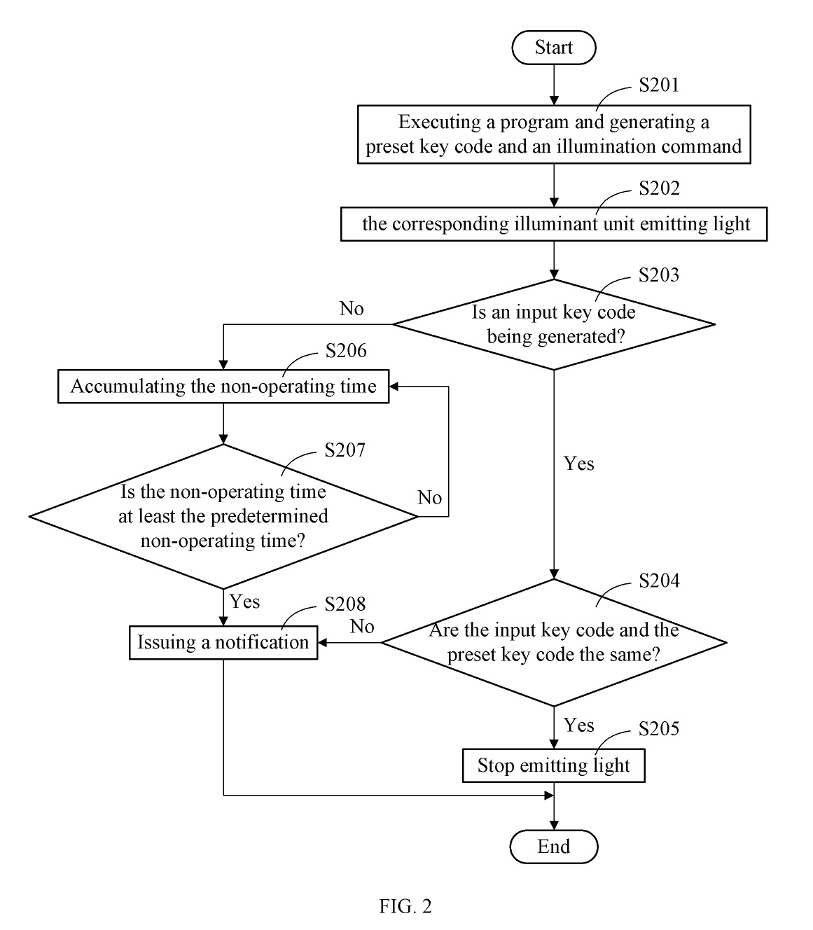

Referring also to FIG. 2, an input system for the input device 100 in combination with the electronic device 200. The input system includes the following steps.

In step S201, executing a program and generating a preset key code and an illumination command. The program may be a dancing game.

In step S202, the corresponding illumination unit 140 emits light. The keys 120 may be transparent keys or translucent keys allowing light emitted by the illumination unit 140 to pass there through.

In step S203, detecting whether an input key code is generated. If it is determined that a key code is generated, the step S204 is implemented. If it is determined that no key code is generated, the step S206 is implemented.

In step S204, comparing whether the preset key code and the input key code are the same code. If it is determined that the preset key code and the input key code are the same code, the right key is activated and the step S205 is implemented. If it determined that the preset key code and the input key code are different, an erroneous key is activated and the step S208 is implemented.

In step S205, the corresponding illumination unit 140 stops emitting light, the procedure is ended.

In step S206, accumulating the non-operating time.

In step S207, comparing the non-operating time and a predetermined non-operating duration. If it determined that the non-operating time is at least the non-operating duration, step S207 is implemented. If it determined that the non-operating time is at least the non-operating duration, the step S208 is implemented.

In step S208, the corresponding notification unit 160 issues a notification. The notification is a vibration, but alternatively issues an image, audio, or video notification, the procedure is ended.

In the disclosed input system, the electronic device identifies a requisite key, which can then be quickly and easily activated. In the event of an erroneous activation the input device issues a prompt notification.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An input device connected with an electronic device, the electronic device comprises an execution unit and a communication unit, the execution unit generates a preset key code and an illumination command, the communication unit sends the preset key code and the illumination command to the input device, the input device comprising:
a plurality of keys each having an exclusive input key code; and
a plurality of illumination units each corresponding to one key, the illumination unit corresponding to the key which input key code is the same with the preset key code adapted to emit light in response to the illumination command so as to prompt the user to press the key which input key code is the same with the preset key code.

2. The input device of claim 1, wherein the key is a transparent key or a translucent key.

3. The input device of claim 1, wherein the input device further comprise a plurality of detection units each corresponding to one key, the electronic device further comprises a first comparison unit, the execution unit sends the preset key code to the first comparison unit, the detection unit adapted to detect any of the keys being deactivated, if a key is activated the detection unit sends an input key code to the first comparison unit through the communication unit, the first comparison unit compares the preset key code and the input key code.

4. The input device of claim 3, wherein if the input key code is the same with the preset key code, the right key is activated, the first comparison unit generates a stop signal, the corresponding illumination unit stops emitting light according to the stop signal.

5. The input device of claim 3, wherein the input device further comprises a plurality of notification units each corresponding to one key, if the input key code is not the same with the preset key code, the erroneous key is activated, the first comparison unit generates an error notification, the notification unit issues a notification according to the error notification.

6. The input device of claim 5, wherein the notification unit is a vibration motor.

7. The input device of claim 5, wherein the electronic device further comprising a determination unit, the determination unit determines whether an input key code is received, if an input key code is received, the determination unit transmits the input key code to the first comparison unit.

8. The input device of claim 7, wherein the electronic device further comprising a timing unit and a second comparison unit, if an input key code is not received, the timing unit measures the non-operating duration according to the timing signal, the second comparison unit comprises a predetermined non-operating duration value, the second comparison unit compares whether the non-operating time is at least the predetermined non-operating duration.

9. The input device of claim 8, wherein if the non-operating time is at least the predetermined non-operating duration, the erroneous key is activated, the second comparison unit generates an error notification, the notification unit issues a notification according to the error notification.

10. The input device of claim 8, wherein the non-operating duration is equal to the length of time required for the execution unit to generate a preset key code.

11. An input device connected with an electronic device, the electronic device comprises an execution unit and a first comparison unit, the execution unit generates a preset key code, the input device comprising:
a plurality of keys;
a plurality of detection units each corresponding to one key, the detection unit adapted to detect whether one of the keys is activated, if a key is activated the detection unit according to the key which is activated generates an input key code, so that the first comparison unit compares the preset key code and the input key code;
if the input key code is different from the preset key code, the first comparison unit generates an error notification; and
a plurality of notification units each corresponding to one key, the notification unit adapted to issue a notification corresponding to the key which is activated according to the error notification, so as to prompt the user that an erroneous key is activated.

12. The input device of claim 11, wherein the notification unit is a vibration motor.

13. An input system for an input device and an electronic device, the input device comprise a plurality of keys each having an exclusive input key code and a plurality of illumination units each corresponding to one key, the electronic device comprise an execution unit generates a preset key code and an illumination command, the input system comprising:
receiving the preset key code and the illumination command; and
the illumination unit corresponding to the key which the input key code is the same with the preset key code emitting light in response to the illumination command so as to prompt the user to press the key which input key code is the same with the preset key code.

14. The input system according to claim 13, the input device further comprises a plurality of detection units each corresponding to one key, if one of the keys is activated the corresponding detection unit generates an input key code; the electronic device further comprises a first comparison unit; after the step of the illumination unit corresponding to the key which the input key code is the same with the preset key code emitting light in response to the illumination command further comprising:
detecting whether an input key code is generated; and
if the input key code is generated, comparing the input key code and the preset key code.

15. The input system according to claim 14, wherein if the input key code and the preset key code are same, the right key is activated, generating a stop signal; and
the illumination unit according to the key which the input key code is the same with the preset key code stop emitting light.

16. The input system according to claim 14, the input device further comprises a plurality of notification units each corresponding one of the keys, if the input key code and the preset key code are different, the wrong key is activated;
generating a warning signal; and
the notification unit according to the key which is activated starts to warning.

17. The input system according to claim 16, wherein the warning is a vibration.

18. The input system according to claim 14, the electronic device further comprises a timing unit and a second comparison unit, the second comparison unit comprises a predetermined non-operating duration value; if no input key code is generated;
accumulating the non-operating time; and
comparing the non-operating time and the predetermined non-operating duration.

19. The input system according to claim 18, if the non-operating time is at least the predetermined non-operating duration, an erroneous key is activated; and
the notification unit issues a notification according to the key which is activated.

20. The input system according to claim 18, the predetermined non-operating duration is equal to the length of time required for the execution unit to generate a preset key code.
